(19) United States
(12) Patent Application Publication
(10) Pub. No.: US 2008/0264469 A1
(43) Pub. Date: Oct. 30, 2008

(54) Solar power unit with integrated primary structure

(75) Inventors: Michael Milbourne, El Granada, CA (US); Peter Young, San Francisco, CA (US)

Correspondence Address: THE MUELLER LAW OFFICE, P.C., 12951 Harwick Lane, San Diego, CA, 92130, US

(73) Assignee: Sol Focus, Inc., Palo Alto, CA (US)

(21) Appl. No.: 11/796,486

(22) Filed: Apr. 27, 2007

(51) Int. Cl. H01L 31/042

(52) U.S. Cl. 136/246

(57) ABSTRACT

A solar power unit which uses at least two mirrors to focus light onto a solar receiver assembly is disclosed. A primary structure for the solar power unit comprises a primary mirror and supporting walls integrally formed around the perimeter of the primary mirror. The integral construction of the primary mirror and supporting walls improves the alignment of components within the solar power unit. Solar power units may be joined together with interlocking features to form a solar energy array.

### RELATED APPLICATION

This application is related to co-pending U.S. Utility patent application Ser. No. ______ [TBD] filed on Apr. 27, 2007 entitled “Solar Power Unit with Enclosed Outer Structure” which is hereby incorporated by reference as if set forth in full in this application for all purposes.

### BACKGROUND OF THE INVENTION

It is generally appreciated that one of the many known technologies for generating electrical power involves harvesting solar radiation and converting it into direct current (DC) electricity. Solar power generation has already proven to be a very effective and “environmentally friendly” energy option, and further advances related to this technology continue to increase the appeal of such power generation systems. In addition to having a design that is efficient in both performance and size, a key factor to commercial success is the ability to manufacture such systems in a cost-effective manner through improvements in manufacturability and component design.

Traditional solar energy conversion is achieved by flat-plate technology, in which solar radiation directly impinges upon a large array of photovoltaic cells. Because the cost of photovoltaic cells and the supply of semiconductor materials are both high, the cost of the large surface areas required for this approach is a deterrent to widespread use. In contrast, concentrator photovoltaic (CPV) systems are solar energy generators which increase the efficiency of converting solar energy to DC electricity by using mirrors to focus the intensity of sunlight onto a small, and thus much less expensive, solar cell.

Solar concentrators which are known in the art utilize parabolic mirrors and Fresnel lenses for focusing incoming solar energy, as well as heliostats for tracking the sun's movements in order to maximize light exposure. A new type of CPV system, disclosed in U.S. Patent Application Publication No. 2006/0266408 A1, entitled “Concentrator Solar Photovoltaic Array with Compact Tailored Imaging Power Units,” utilizes two curved mirrors which allow for a compact yet structurally robust design. In this design, solar energy enters the assembly through a front panel. The solar rays reflect off a primary mirror onto a secondary mirror, which in turn reflects and focuses solar energy onto a photovoltaic cell. A back panel and housing enclose the assembly to protect it from environmental elements and to provide structural integrity. The surface area of the solar photovoltaic cell in such a system is much smaller than what is required for non-concentrating systems, for example less than 1% of the entry window surface area. Thus, the reduction in the amount of expensive photovoltaic material results in a greatly decreased cost of the overall assembly.

However, although solar concentrators are feasible in principle and have been under development for many years, they have yet to produce energy at prices which are competitive enough to attain widespread commercial success. The ability to produce energy at a cost-efficient rate hinges on a design which is highly efficient at producing energy, and which minimizes the cost of manufacturing the system. Because the receiving area of the solar cell is so small relative to that of the power unit, the need for the mirrors to be accurately aligned to focus the sun's rays onto the solar cell is important to achieving the desired efficiency of such a solar concentrating system. Accurate placement of the solar cell and primary and secondary mirrors requires precision manual operations and specialized tooling. Such tooling costs and inherent tolerance errors become propagated when constructing an array of many concentrator units. Components which are designed in such a way to reduce material costs and to simplify the assembly process would greatly improve the chances of a solar energy system to be successful. Additional considerations such as ease of installation, serviceability, and durability against environmental conditions also are important to the commercial success of a design.

Solar energy systems known in the art often utilize components which are fabricated from metal. One cost-effective process for production of metal components is sheet-metal stamping. Stamping involves forming and cutting sheets of metal into precise and sometimes complex shapes through the use of dies. For instance, U.S. Pat. No. 4,150,663 entitled “Solar Energy Collector and Concentrator” discloses a design in which one or more hemispherical mirrors may be stamped from sheet metal. U.S. Pat. No. 5,153,780 entitled “Method and Apparatus for Uniformly Concentrating Solar Flux for Photovoltaic Applications” describes a stepped solar reflector dish which may be formed by sheet metal stamping. In U.S. Pat. No. 4,716,258 entitled “Stamped Concentrators Supporting Photovoltaic Assemblies,” stamping is used to produce a one-piece concentrator unit with an array of slatted, louvered reflectors.

In addition to optical elements, supportive elements in solar power systems may also be formed by sheet metal stamping. In U.S. Pat. No. 4,324,028 entitled “Method of Fabricating a Solar Absorber Panel,” stamping is used to form slotted absorber panels and tabbed fluid ducts. The panels and ducts may then be attached to each other to form the assembly. U.S. Pat. No. 4,135,493 entitled “Parabolic Trough Solar Energy Collector Assembly” states that the ribs used to support the parabolic trough surface may be easily formed by stamping and then attached to the main structure.

As an alternative to sheet metal fabrication, patent application publication U.S. 2006/0231133 A1, entitled “Concentrating Solar Collector with Solid Optical Element,” describes an optical element which may be molded from optically suitable materials such as glass or clear plastic. Mirrors are formed by depositing or plating reflective films onto the faces of the optical element. Light travels within the solid optical element, reflecting off primary and secondary mirror surfaces to then be focused onto a photovoltaic cell. The solid element thus combines two mirrors into one component, which are inherently aligned.

While processes such as stamping and molding have been used in solar energy systems to fabricate various parts, there is the long-felt need to further improve the manufacturability of such systems in order to make solar energy more successful in the energy market. Reducing the number of components, improving repeatable and accurate alignment of parts, and decreasing material costs while preserving or increasing functional performance are all aspects which continue to be sought after in the solar concentrator industry. This is even more of a challenge in consideration of the fact that each new design requires solutions particular to its individual construction. Improvements which additionally have a positive impact on ease of installation, serviceability, and durability against environmental conditions are also highly important.

### SUMMARY OF THE INVENTION

The present invention is a solar power unit which uses one or more mirrors to focus light onto a solar receiver assembly. A primary structure for the solar power unit comprises a primary mirror and supporting walls integrally formed around the perimeter of the primary mirror. The integral construction of the primary mirror and supporting walls improves the alignment of components within the solar power unit. In one embodiment, the primary structure is a hexagonal shape fabricated by sheet-metal stamping. Solar power units may be joined together with interlocking features to form a solar energy array.

### BRIEF DESCRIPTION OF THE DRAWINGS

FIG. 1 provides a cross-sectional view of a basic solar concentrator unit;

FIG. 2 shows a cross-sectional view of an improved solar power unit;

FIG. 3 illustrates a cross-sectional view of a solar power unit with an alternative primary structure;

FIG. 4 is a perspective view of a primary structure;

FIGS. 5A and 5B give cross-sectional views of methods of joining primary structures;

FIG. 6 shows a perspective view of a primary structure with alternative interlocking means;

FIG. 7 is a diagram of interlocking solar power units in an array;

FIG. 8 depicts a perspective view of yet another embodiment of a power unit with interlocking features;

FIG. 9 provides a perspective view of a power unit with alternating walls;

FIG. 10 illustrates a cross-sectional view of a solar power unit with a solid construction primary structure;

FIG. 11A is a plan view of power units with spacer rods;

FIG. 11B is a cross-sectional view of power units with spacer rods;

FIG. 11C provides a perspective view of a solar array with a single front panel; and

FIGS. 12A and 12B are simplified flowcharts illustrating basic steps in the assembly process.

### DETAILED DESCRIPTION OF THE EMBODIMENTS

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

The inventions described in this disclosure may be used with a solar power unit design incorporating optically aligned primary and secondary mirrors. The solar power unit design is described in detail in related, co-pending patent applications as follows: (1) “Concentrator Solar Photovoltaic Array with Compact Tailored Imaging Power Units;” U.S. Patent Application Publication No. 2006/0266408 A1; filed May 26, 2005; and (2) “Optical System Using Tailored Imaging Designs;” U.S. Patent Application Publication No. 2006/0274439 A1; filed Feb. 9, 2006, which claims priority from U.S. provisional patent application No. 60/651,856 filed Feb. 10, 2005; all of which are hereby incorporated by reference as set forth in full in this application for all purposes. Note that variations on the design described in the co-pending applications may be achieved by modifying specific steps and/or items described herein while still remaining within the scope of the invention as claimed.

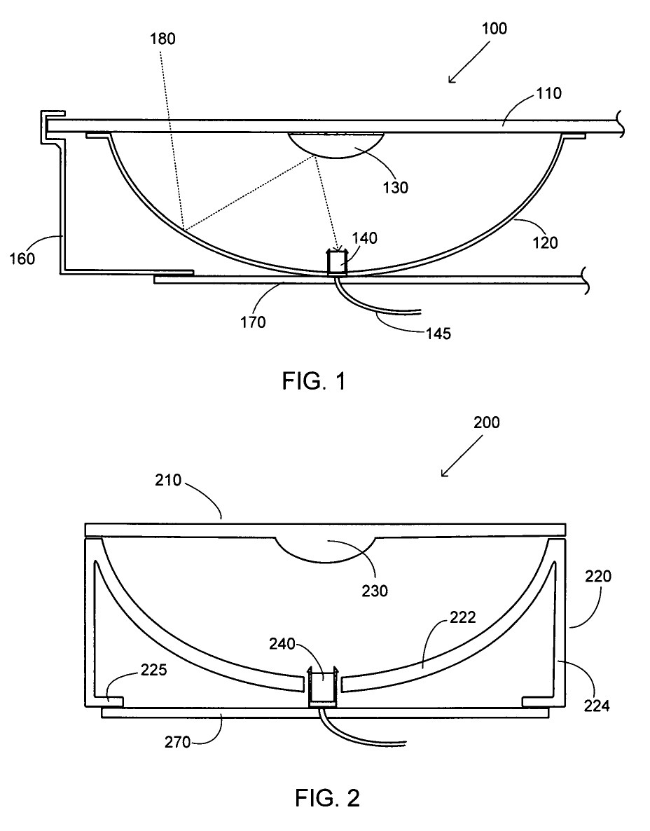

In FIG. 1, an exemplary cross-sectional view of the solar power unit 100 in the afore-mentioned co-pending patent applications is portrayed. Note that for commercial application, the single power unit 100 would typically be replicated into an array of adjoining power units to form a complete solar panel. A front panel 110 covers the main optical elements of a primary mirror 120, a secondary mirror 130, and a solar receiver assembly 140. Protective front panel 110 is a substantially planar surface, such as a window or other transparent covering, which provides structural integrity for a power unit and protection for other components thereof. Sunlight 180 enters the solar unit 100 through front panel 110 and reflects off of primary mirror 120 to secondary mirror 130, where it is further reflected and focused onto receiver assembly 140. In one embodiment, receiver assembly 140 houses an optical rod and a photovoltaic cell where the intensified sunlight is converted into electrical energy. Energy is delivered out of the solar power unit 100 through power output wire 145.

In reference still to FIG. 1, primary mirror 120 and secondary mirror 130 are substantially co-planar, at least a portion of both mirrors being in contact with front panel 110. In one exemplary embodiment, primary mirror 120 is generally circular and may have a diameter of approximately 280 mm and a depth of approximately 70 mm. Secondary mirror 130 is also generally circular, and is typically a first surface mirror using silver and a passivation layer formed on a substrate of soda-lime glass. In one embodiment, secondary mirror 130 may have a diameter of approximately 50 mm, and is adhered to front panel 110.

In this original configuration of the solar concentrator system as depicted in FIG. 1, housing 160 and back panel 170 are used to maintain the mirrors 120 and 130 and front panel 110 in alignment. Housing 160 is a frame designed to enclose the total number of power units in a given solar energy array, and back panel 170 is used to mount solar receivers 140 in the array and to serve as a heat dissipation element. Housing 160 and back panel 170 may be attached to the solar energy system by bolts, screws, or similar means (not shown) well-known in the art. Because panels 110 and 170, housing 160, and mirrors 120 and 130 are all separate components, there is inherent tolerance error in positioning the components during assembly. This error is compounded by the tolerance stack-up resulting from multiple parts depending on alignment with each other. Thus, proper alignment of the optical elements relies heavily on proper tooling, such as mounting templates, and on precise manual assembly. Alignment errors and tooling costs are further multiplied in an array of many solar power units. Moreover, specific tooling must be made for each different size of array, such as an array of 10 cells or 32 cells.

Turning now to FIG. 2, a cross-sectional view of an improved solar power unit 200 is shown. As in FIG. 1, a front panel 210, back panel 270, secondary mirror 230, and solar receiver assembly 240 are shown. However, primary mirror 120 and housing 160 are replaced with primary structure 220, which serves as both a primary mirror and supporting walls. Because primary mirror portion 222 and supporting walls 224 are integrally formed, there is negligible or no error in aligning the primary mirror in the solar power unit 200. In addition, primary structure 220 provides modular construction of an array, which allows for individual repair of power units as well as flexibility in forming various sizes of arrays. FIG. 2 also depicts front panel 210 and secondary mirror 230 being integrally formed, which eliminates alignment error for secondary mirror 230. By aligning the perimeters of front panel 210 and primary structure 220, the secondary mirror would then be centered over primary mirror 222.

Still referring to FIG. 2, primary structure 220 may include flanges 225 to which back panel 270 may be attached. Flanges may be short extensions as shown or may extend inward to solar receiver, in which case the extended flanges form a back panel for and provide additional stability to power unit 200. Primary structure 220 may be formed by processes such as sheet-metal stamping, plastic injection-molding, metal casting, and the like. The wall thickness of the primary structure 220 is desirably thin enough to maintain a lightweight assembly and reasonable material cost while having a value large enough for structural strength, such as in the range of 0.05 mm to 3.0 mm. The material for primary structure 220 is preferably chosen to have a similar coefficient of thermal expansion, also known as “CTE” or “α,” as front panel 210 to minimize thermal stresses. For instance, a primary structure 220 fabricated from carbon steel having a CTE of 10.8 in/in/° F. would be compatible with glass front panel 210 having a CTE of 8.5 in/in/° F.

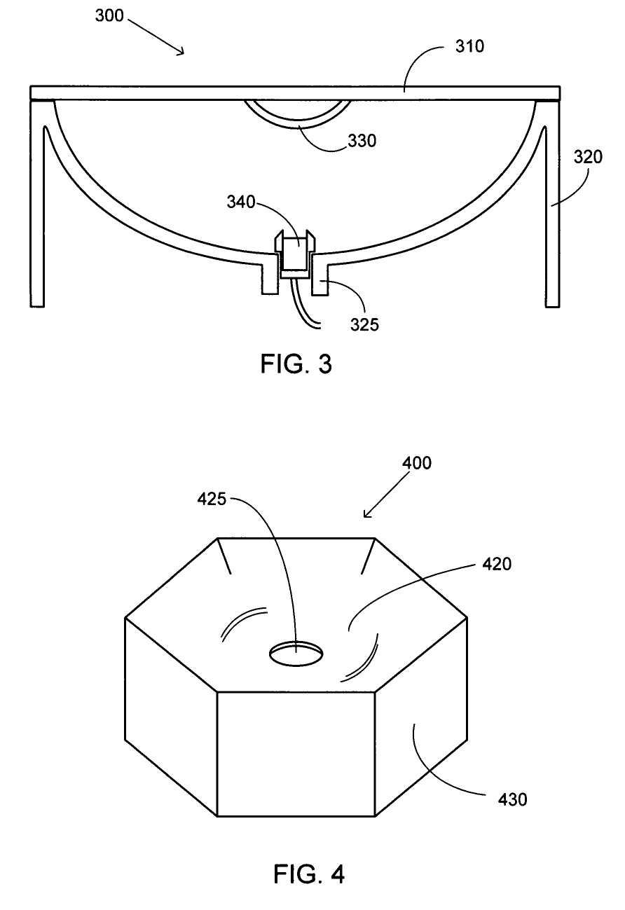

Moving to FIG. 3, an alternative embodiment of the primary structure 320 is illustrated. In this embodiment, solar concentrator unit 300 does not include a back panel. Instead, primary structure 320 includes a flanged mounting hole 325 into which solar receiver 340 is inserted. The gap between solar receiver 340 and hole 325 is sealed to create a weather-proof solar concentrator unit. Sealants may include silicone, silicone compounds incorporating butyl or urethane, or other polymers which can accommodate flexure between parts. FIG. 3 also demonstrates an alternative embodiment of secondary mirror 330, in which secondary mirror 330 is a shell-type construction formed by sheet-metal stamping or injection-molding and then bonded to front panel 310. This embodiment results in a lighter weight component, an aspect which is beneficial in an array of many solar concentrator units.

FIG. 4 is a perspective view of a primary structure 400. In this embodiment, the curved primary mirror 420 is supported by walls 430 which form a hexagonal shape. When several hexagonal structures are combined into an array, the resulting honeycomb pattern is inherently resistant to structural stresses such as wind deformation loads. Alternatively, the perimeter of primary structure 400 could take the form a square or other polygonal shape. A circular mounting space 425 for locating the solar receiver assembly is shown as a hole in the center of primary structure 400. However, the space 425 could take the shape of a polygon or more complex shapes as necessary to accommodate the solar receiver assembly. For instance, the solar receiver may include external protrusions to enhance heat sinking or to facilitate securing the receiver assembly into mounting space 425. In yet another embodiment, instead of a through-hole, the space 425 could take the form of a recessed pocket into which the solar receiver assembly is seated. In that instance, only a small hole in the bottom of the pocket would be required for allowing the power output wire to exit.

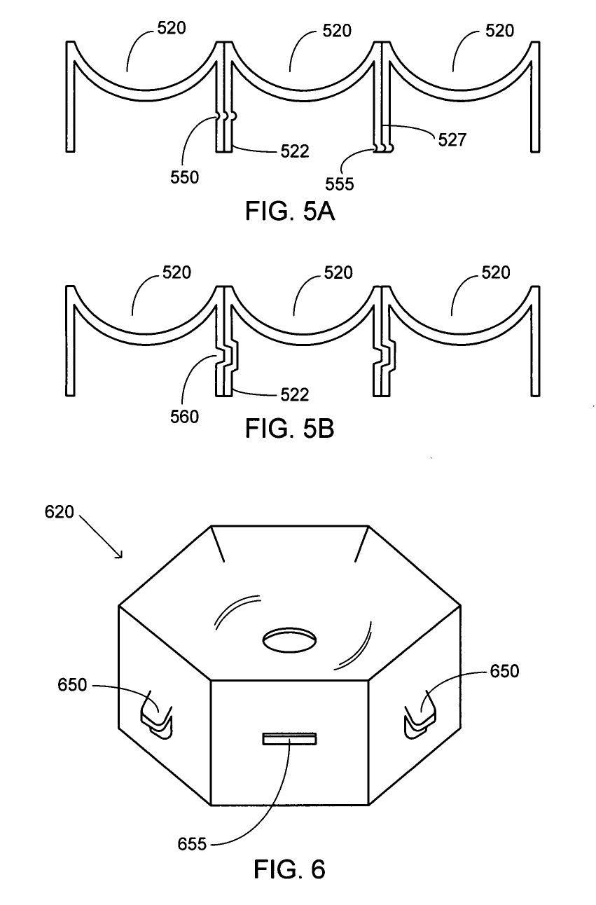

Now turning to FIGS. 5A and 5B, methods of joining solar concentrator units into an array are shown. While solar concentrator units with planar walls as depicted in FIG. 4 may be connected by adhesive or by using fasteners such as rivets or screws, alternative methods may be used to facilitate manufacturing. In FIGS. 5A and 5B, cross-sections of three primary structures 520 are shown to be adjacent as in a solar array. In FIG. 5A, the walls of two adjacent structures are crimped together. Crimped joint 550 is located mid-height along the wall 522, whereas crimped joint 555 shows an alternative location at the foot of the wall 527. The crimped joints 550 and 555 may be of minimal width or may extend along a longer length, such as, for example, the length of one side of a hexagonal perimeter. In a further embodiment, FIG. 5B illustrates bumps 560 which may be formed into the walls 522 of primary structures 520 for interlocking purposes.

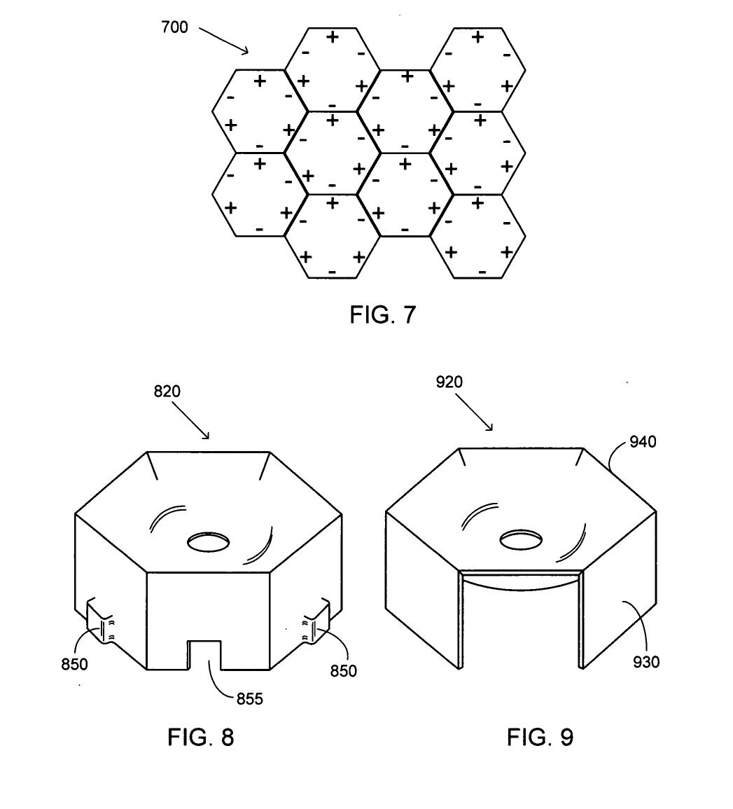

FIG. 6 depicts another means for interlocking solar units into an array. In this perspective view, outer structure 620 is seen to have tabs 650 cut out of alternating walls. In the remaining walls, a corresponding slot 655 is cut. The tabs 650 may be simply inserted into slots 655, or may be inserted and then folded to more securely lock the units together. In another variation not shown, the tabs may incorporate a hook feature at their tips, and a slight outward bend of the tabs would provide a snap lock into mating slots. FIG. 7 is a schematic of how mating features may be arranged in an array 700, where “+” represents walls with tabs 650 and “−” represents walls with slots 655. As mentioned previously, the primary structures may take the form of other polygonal shapes such as squares and still utilize the same alternating arrangement for interlocking features.

FIG. 8 illustrates another type of mating feature which may be used to interlock units. Instead of tabs and slots, protrusions 850 may be used to fit into openings 855 located in alternating walls of primary structure 820. The shape of the protrusion may be altered to have, for example, an angular or rounded dovetail shape to provide additional interlocking between units.

In yet another embodiment depicted in FIG. 9, primary structure 920 may be fabricated with “discontinuous” supporting walls; that is, supporting walls 930 formed only on alternating sides of perimeter 940. In this manner, interlocking units would share one supporting wall rather than having two walls next to each other. That is, the “+” of FIG. 7 would represent sides with a wall, and “−” would represent the open space of the adjacent unit. As a variation of FIG. 9, the walls 930 may be inclined slightly outward. This would provide additional interlocking support between solar power units as the angled walls fit into an open wall space in an adjoining unit.

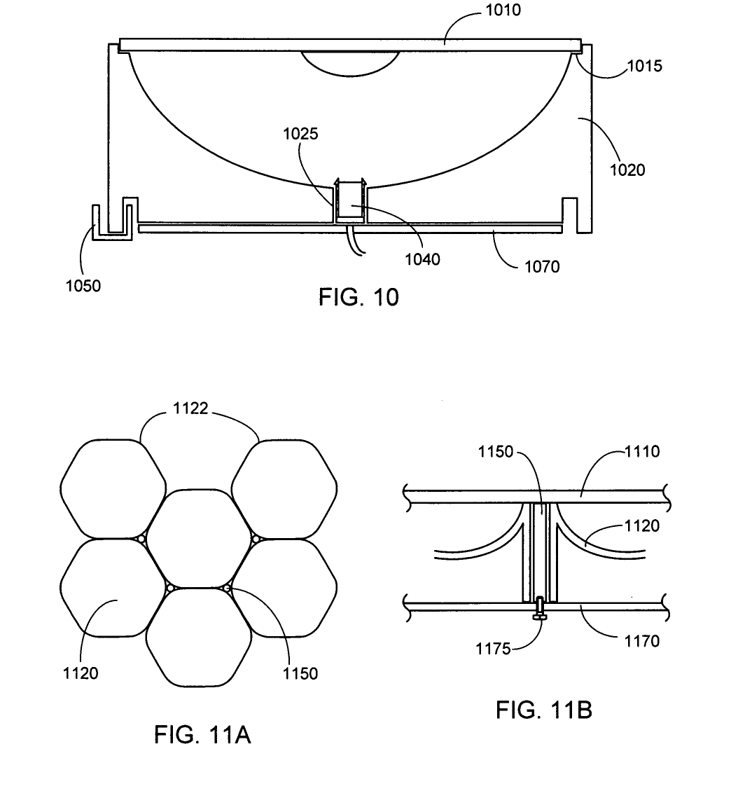

Turning now to FIG. 10, an alternative construction of primary structure 1020 is shown. In this configuration, primary structure 1020 is molded from plastic as a solid piece rather than a shell-type structure. With this construction, groove 1015 for aligning front panel 1010 may be integrally formed around the upper opening of primary structure 1020. Hole 1025 is formed in primary structure 1020 for inserting solar receiver 1040. Solar receiver 1040 may be attached directly to primary structure 1020 by means such as an adhesive sealant, or may be mounted to back panel 1070 which would then be secured to primary structure 1020 by adhesive, screws, or other means. FIG. 10 also depicts clips 1050 as a means for interlocking units. Note that the clips 1050 may also be used with the thin-walled structures of FIGS. 2-9, or similarly, the interlocking features of FIGS. 2-9 may be applied to FIG. 10.

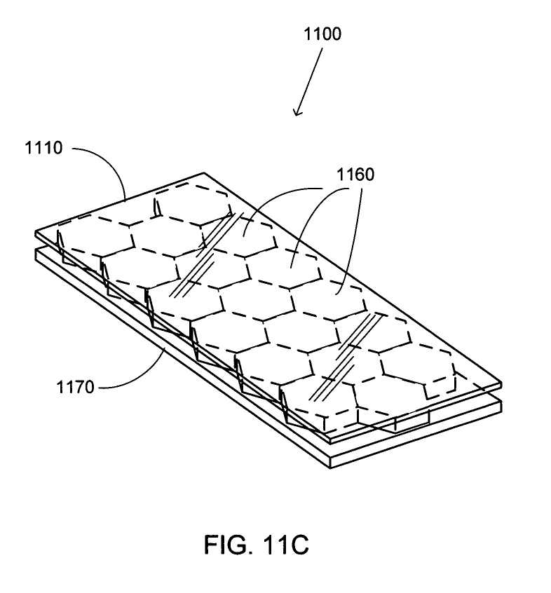

While the solar concentrator units discussed thus far have been shown to each have their own front panels, this need not necessarily be the case. It is also possible to have individual units joined together without front panels, and then have a single front panel placed over the entire array. For further structural stability, FIGS. 11A and 11B illustrate the use of spacer rods 1150 to support front panel 1110. In plan view FIG. 11A, primary structures 1120 are shown to have rounded corners 1122. Spacer rods 1150 are placed in the resulting open spaces formed by the rounded corners 1122. FIG. 11B depicts a cross-sectional view of such an arrangement, where spacer rod 1150 has approximately the same height as primary structure 1120. Spacer rod 1150 is secured to front panel 1110 and back panel 1170 by fastener 1175 or by bonding. The presence of spacer rods 1150 throughout the array helps minimize bowing of front panel 1110 over the large surface area of the array, and relieves the weight of the panel from the solar concentrator units.

FIG. 11C shows a perspective view of an assembled solar array 1100 in which one front panel 1110 is used to cover the entire array 1100. Back panel 1170 is present in this configuration, and may serve to secure the solar receivers within each solar concentrator unit 1160 as described previously. In this depiction, no spacer rods are used. Instead, the solar concentrator units 1160 may be bonded to front panel 1110.

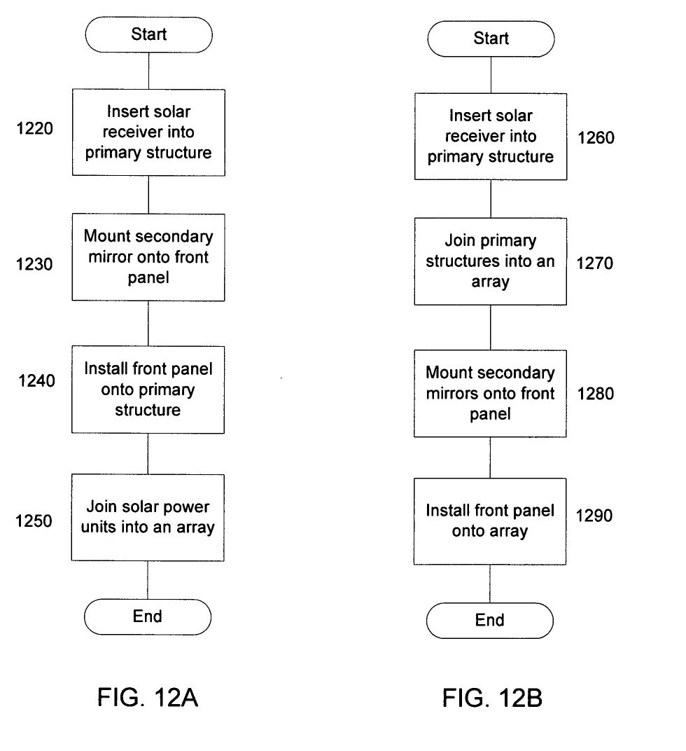

Now referring to FIGS. 12A and 12B, these figures depict simplified flowcharts describing the steps for fabricating a solar concentrator array. FIG. 12A is directed toward units which contain their own front panels, whereas FIG. 12B is directed toward an array in which one front panel covers the entire array. In FIG. 12A, the manufacturing process begins with step 1220, in which the solar receiver assembly is inserted into the primary structure. Step 1220 could also include attachment of the back panel in configurations such as in FIG. 2, where the solar receiver assembly is secured to the back panel. Next, the secondary mirror is mounted onto the front panel in step 1230. In step 1240, the front panel with secondary mirror is installed onto the primary structure. The process is completed in step 1250, where the individual units are joined into an array by bonding or other interlocking means as described previously.

FIG. 12B is similar to FIG. 12A in that the first operation in the manufacturing process is to insert the solar receiver assembly into the primary structure in step 1260. At this point, the primary structures may be joined into an array in step 1270 by methods such as bonding or fastening adjacent walls together, using interlocking features, or bonding primary structures onto a single back panel for the entire array. In step 1280, secondary mirrors are positioned and mounted onto the front panel in such a way that one secondary mirror will be enclosed within each primary structure. This step may entail using a mounting template or an automated process to accurately place the secondary mirrors. To complete the solar energy array, the front panel is then placed onto the array of primary structures in step 1290.

Although embodiments of the invention have been discussed primarily with respect to specific embodiments thereof, other variations are possible. Lenses or other optical devices might be used in place of, or in addition to, the primary and secondary mirrors or other components presented herein. For example, a Fresnel type of lens could be used to focus light on the primary optical element, or to focus light at an intermediary phase after processing by a primary optical element.

It may be possible to use non-planar materials and surfaces with the techniques disclosed herein. Other embodiments can use optical or other components for focusing any type of electromagnetic energy such as infrared, ultraviolet, radio-frequency, etc. There may be other applications for the fabrication method and apparatus disclosed herein, such as in the fields of light emission or sourcing technology (e.g., fluorescent lighting using a trough design, incandescent, halogen, spotlight, etc.) where the light source is put in the position of the photovoltaic cell. In general, any type of suitable cell, such as a photovoltaic cell, concentrator cell or solar cell can be used. In other applications it may be possible to use other energy such as any source of photons, electrons or other dispersed energy that can be concentrated.

Steps may be performed by hardware or software, as desired. Note that steps can be added to, taken from or modified from the steps in this specification without deviating from the scope of the invention. In general, any flowcharts presented are only intended to indicate one possible sequence of basic operations to achieve a function, and many variations are possible.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A solar concentrator unit, comprising:
a primary structure having an upper surface and a bottom surface, said primary structure comprising a primary mirror and a support structure, said support structure forming supporting walls around the perimeter of said primary mirror, wherein said primary mirror and said support structure are integrally formed;
a front panel covering the upper surface of said primary structure; and
a solar receiver to convert solar energy into electricity, said solar receiver positioned in said primary structure to receive solar energy reflected from said primary mirror.

2. The solar concentrator unit of claim 1, wherein said primary structure is formed by sheet metal stamping.

3. The solar concentrator unit of claim 2, wherein said primary structure is made of steel.

4. The solar concentrator unit of claim 1, wherein said primary structure is formed by plastic molding.

5. The solar concentrator unit of claim 1, further comprising a secondary mirror mounted to said front panel and positioned to reflect solar energy from said primary mirror to said solar receiver.

6. The solar concentrator unit of claim 5, wherein said secondary mirror is formed by sheet metal stamping.

7. The solar concentrator unit of claim 5, wherein said primary structure is used to align said secondary mirror with said primary mirror.

8. The solar concentrator unit of claim 1, wherein said perimeter of said primary mirror forms a hexagonal shape.

9. The solar concentrator unit of claim 1, wherein said front panel is attached to said primary structure.

10. The solar concentrator unit of claim 1, further comprising a back panel covering said bottom surface of said primary structure.

11. The solar concentrator unit of claim 1, wherein said supporting walls are discontinuous around the perimeter of said primary mirror.

12. The solar concentrator unit of claim 1, said primary structure further comprising means for interlocking solar concentrator units into an array.

13. The solar concentrator unit of claim 1, wherein said primary mirror further comprises a mounting space, wherein said solar receiver is positioned in said mounting space.

14. A solar concentrator array, comprising:
(a) a plurality of solar concentrator units with upper surfaces, each of said solar concentrator units comprising:
a primary structure comprising a primary mirror with a perimeter and a support structure, said support structure forming supporting walls around the perimeter of said primary mirror, wherein said primary mirror and said support structure are integrally formed;
a secondary mirror positioned to reflect solar energy reflected from said primary mirror; and
a solar receiver to convert solar energy into electricity, wherein said solar receiver is positioned to receive solar energy reflected from said secondary mirror; and
(b) means for covering the upper surfaces of said plurality of solar concentrator units.

15. The solar concentrator array of claim 14, wherein said means for covering the upper surfaces of said plurality of solar concentrator units comprises one front panel covering said solar concentrator array.

16. The solar concentrator array of claim 14, wherein said means for covering the upper surfaces of said plurality of solar concentrator units comprises a plurality of front panels, wherein each of said front panels corresponds to each of said solar concentrator units.

17. The solar concentrator array of claim 14, said primary structure further comprising means for interlocking said solar concentrator units.

18. The solar concentrator array of claim 14, wherein said solar concentrator units may be individually removed from said solar concentrator array.

19. The solar concentrator array of claim 14, wherein said primary structure is formed by sheet metal stamping.

20. A method of assembling a solar concentrator unit, comprising:
positioning a solar receiver in a primary structure having an upper surface and a bottom surface, said solar receiver capable of converting solar energy into electricity, said primary structure comprising a primary mirror with a perimeter and a support structure, wherein said primary mirror is positioned to reflect said solar energy, wherein said support structure forms supporting walls around the perimeter of said primary mirror, and wherein said primary mirror and said support structure are integrally formed; and
covering the upper surface of said primary structure with a front panel.

21. The method of assembling a solar concentrator unit of claim 20, further comprising the step of covering the bottom surface of said primary structure with a back panel.

22. The method of assembling a solar concentrator of claim 20, further comprising the step of mounting a secondary mirror to said front panel, wherein said secondary mirror is positioned to reflect solar energy from said primary mirror to said solar receiver.
